(19) United States
(12) Patent Application Publication
(10) Pub. No.: US 2016/0091534 A1
(43) Pub. Date: Mar. 31, 2016

(54) CURRENT SENSOR

(71) Applicant: Semes Co., Ltd., Cheonan-si (KR)

(72) Inventors: Danielyan EMMA, Cheonan-si (KR); Dok Hyun SON, Cheonan-si (KR)

(21) Appl. No.: 14/867,330

(22) Filed: Sep. 28, 2015

(30) Foreign Application Priority Data
Sep. 30, 2014 (KR) 10-2014-0131552

(51) Int. Cl. G01R 15/18; H01J 37/32; C23C 16/50

(52) U.S. Cl. CPC G01R 15/18; C23C 16/50; H01J 37/32082; H01J 37/3266

(57) ABSTRACT

A current sensor is provided. The current sensor includes a signal transmission unit through which a power signal is transmitted, a current measurement probe spaced apart from a side of the signal transmission unit and having a loop structure so as to partition an area which links together with a magnetic field induced according to the power signal transferred through the signal transmission unit, and a signal processing unit measuring an induced current induced at the current measurement probe by a magnetic field, which is generated according to the power signal transferred through the signal transmission unit, and calculating a current value of the power signal transferred into the signal transmission unit from a value of the measured induced current.

### CROSS-REFERENCE TO RELATED APPLICATIONS

A claim for priority under 35 U.S.C. §119 is made to Korean Patent Application No. 10-2014-0131552 filed Sep. 30, 2014, in the Korean Intellectual Property Office, the entire contents of which are hereby incorporated by reference.

### BACKGROUND

Embodiments of the inventive concepts described herein relate to a current sensor, and more particularly, relate to a voltage-current sensor (VI sensor) for measuring voltage and current of a RF power signal.

A current sensor with a cylindrical probe encompassing a RF load is known as a current sensor for measuring an RF power current flowing into the RF load. A voltage-current probe with matching directivity is disclosed in the KR Patent Publication No. 1999-0072975 filed Sep. 27, 1999. Recently, as a process for manufacturing semiconductor devices and flat panel display devices becomes increasingly fine and sophisticated, an RF power source need be controlled more sophisticatedly. However, a conventional current sensor has a disadvantage that a measurement error about complex load is relatively large.

### SUMMARY

Embodiments of the inventive concepts provide a current sensor capable of measuring a current of an RF power source accurately.

One aspect of embodiments of the inventive concept is directed to provide a voltage-current sensor (e.g., a VI sensor) in which impedance measurement accuracy for a load is high.

Another aspect of embodiments of the inventive concept is directed to provide a current sensor including a signal transmission unit through which a power signal is transmitted, a current measurement probe spaced apart from a side of the signal transmission unit and having a loop structure so as to partition an interlinkage area which interlinks with a magnetic field induced according to the power signal transferred through the signal transmission unit, and a signal processing unit measuring an induced current induced at the current measurement probe by a magnetic field, which is generated according to the power signal transferred through the signal transmission unit, and calculating a current value of the power signal transferred into the signal transmission unit from a value of the measured induced current.

The current sensor may further include a housing supporting opposite ends of the signal transmission unit and having a hollow portion therein, and a voltage measurement probe disposed in the hollow portion to be spaced apart by a predetermined distance from the signal transmission unit, including a conductor, and formed in a flat-plate shape.

The current sensor may further include insulating materials formed at a first connecting portion between the housing and the signal transmission unit, at a second connecting portion between the housing and the current measurement probe, and at a third connecting portion of the housing and the voltage measurement probe, respectively.

The signal processing unit may be further configured to measure a voltage on the voltage measurement probe generated according to an electric field from the signal transmission unit and to calculate a voltage value of the power signal transferred into the signal transmission unit from the measured voltage value of the voltage measurement probe.

The signal processing unit may measure a phase of the power signal from the measured current and voltage values of the power signal transferred into the signal transmission unit, to measure a load impedance.

The current measurement probe may include a rectangular loop member disposed in the hollow portion to be spaced apart by a predetermined distance from the signal transmission unit, including a conductor, and having an open-loop shape at one side of which a gap is formed, a connecting portion extended to pass through the housing from one end of the loop member and including a conductor, and a connector disposed at an external surface of the housing to connect the connecting portion and the signal processing unit.

Still another aspect of embodiments of the inventive concept is directed to provide a current sensor including a signal transmission unit through which a power signal is transmitted, and a current measurement probe spaced apart from a side surface of the signal transmission unit and having a loop structure to partition an area which links together with a magnetic field induced according to the power signal transferred into the signal transmission unit.

The current measurement probe may include a housing supporting opposite ends of the signal transmission unit and including a hollow portion therein; and a rectangular loop member spaced apart by a predetermined distance from the signal transmission unit, including a conductor, and having an open-loop shape at one side of which a gap is formed.

Still another aspect of embodiments of the inventive concept is directed to provide a plasma substrate processing apparatus including a plasma process chamber forming plasma to treat a substrate, an RF power supply unit supplying an RF power to the plasma process chamber, and a current sensor disposed between the RF power supply unit and the plasma process chamber and measuring a current value of the RF power, the current sensor may include a signal transmission unit through which a power signal is transmitted, a current measurement probe spaced apart from a side of the signal transmission unit and having a loop structure so as to partition an area which links together with a magnetic field induced according to the power signal transferred through the signal transmission unit, and a signal processing unit measuring an induced current induced at the current measurement probe by a magnetic field, which is generated according to the power signal transferred through the signal transmission unit, and calculating a current value of the power signal transferred into the signal transmission unit from a value of the measured induced current.

Other aspects, advantages, and salient features of the disclosure will become apparent to those skilled in the art from the following detailed description, which, taken in conjunction with the annexed drawings, discloses various embodiments of the inventive concept.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a diagram schematically illustrating a plasma substrate processing apparatus including a current sensor according to an embodiment of the inventive concept;

FIG. 2 is a perspective view of a current sensor according to an embodiment of the inventive concept;

FIG. 3 is a partially-cut perspective view of a current sensor according to an embodiment of the inventive concept;

FIG. 4 is a vertical cross-sectional view of a current sensor according to an embodiment of the inventive concept; and

FIG. 5 and FIG. 6 are graphs illustrating a load measurement error of a current sensor, compared to a conventional example, according to an embodiment of the inventive concept.

### DETAILED DESCRIPTION

Other advantages and features and methods of accomplishing the same of the inventive concept may be understood more readily by reference to the following detailed description of an embodiment and the accompanying drawings. However, the scope and spirit of the inventive concept may not be limited thereto. The scope of the inventive concept is to be defined only by the appended claims. Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein. Additionally, well-known elements of exemplary embodiments of the invention will not be described in detail or will be omitted so as not to obscure the relevant details of the invention. Throughout the drawings and the detailed description, unless otherwise described, the same drawing reference numerals will be understood to refer to the same elements, features, and structures. The relative size and depiction of these elements may be exaggerated or reduced for clarity, illustration, and convenience.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises,” “comprising,” “includes,” “including,” “have,” “having” or variants thereof when used herein, specify the presence of stated features, integers, steps, operations, elements, and/or components, but do not preclude the presence or addition of one or more other features, integers, steps, operations, elements, components, and/or groups thereof. It will be understood that when an element or layer is referred to as being “on”, “connected to”, “coupled to”, or “adjacent to” another element or layer, it can be directly on, connected, coupled, or adjacent to the other element or layer, or intervening elements or layers may be present. In contrast, when an element is referred to as being “directly on,” “directly connected to”, “directly coupled to”, or “immediately adjacent to” another element or layer, there are no intervening elements or layers present.

A current sensor according to embodiments of the inventive concept may include a current measurement probe having a rectangular loop structure such that a magnetic field induced by a radio frequency (RF) power transmitted through a signal transmission unit links together with a wide loop area and, thus, a current value of the RF power transferred into the signal transmission unit is accurately measured.

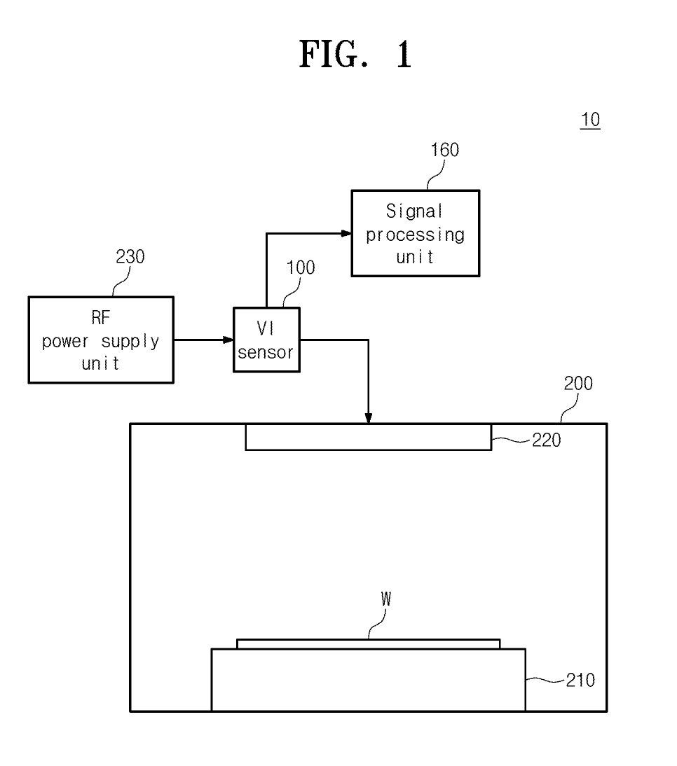

FIG. 1 is a diagram schematically illustrating a plasma substrate processing apparatus 10 having a current sensor according to an embodiment of the inventive concept. Below, an embodiment of the inventive concept will be exemplified as a current sensor according to an embodiment of the inventive concept is a current sensor for measuring a current from an RF power source supplied to a plasma processing chamber 200 in the plasma substrate processing apparatus 10. Furthermore, the current sensor according to an embodiment of the inventive concept may be used to measure a signal current in various fields as well as the plasma substrate processing apparatus 10.

Referring FIG. 1, the plasma substrate processing apparatus 10 according to embodiments of the inventive concept may include a plasma processing chamber 200 generating a plasma and treating a substrate W, an RF power supply unit 230 generating a radio frequency (RF) power to be applied to an electrode 220 of the plasma processing chamber 200, and a current sensor 100 disposed between the RF power supply unit 230 and the electrode 220 of the plasma processing chamber 200 and measuring a current value of an RF power which the RF power supply unit 230 generates and is transmitted to the electrode 220. Although not shown in FIG. 1, the plasma substrate processing apparatus 10 may further include a component for performing impedance matching, such as an impedance matching unit, between the RF power supply unit 230 and the plasma processing chamber 200.

A substrate W may be, for example, a semiconductor substrate where semiconductor devices are manufactured, a glass substrate where flat panel display devices are manufacture, and the like. The substrate W may be treated using an etching process, a chemical vapor deposition process, an ashing process, a cleaning process, and the like. The plasma substrate processing apparatus 10 may be a capacitive coupled plasma (CCP) apparatus, an inductive coupled plasma (ICP) apparatus, a CCP/ICP complex apparatus, a microwave plasma apparatus, or any other plasma substrate processing apparatus.

The plasma processing chamber 200 may provide a space in which the substrate W is treated. The plasma processing chamber 200 may have a hermetically sealed structure to maintain vacuum. In an embodiment, the plasma processing chamber 200 may have a hollow cube form, a hollow cylinder form, or any other form. The plasma processing chamber 200 may include a gas supply port (not illustrated) for forming plasma and supplying a source gas for processing the substrate W and a gas discharge port (not illustrated) for discharging a gas in the plasma processing chamber 200. The gas supply port may be disposed at a side surface or an upper surface of the plasma processing chamber 200. In the case that the gas supply port is disposed at the upper surface of the plasma processing chamber 200, a shower head for uniformly supplying a process gas to the substrate W may be disposed at an inner upper portion of the plasma process chamber 200. The gas discharge port may be disposed at a lower surface or a lower side surface of the plasma processing chamber 200. An unreacted source gas and a by-product of a substrate treating process may be discharged via the gas discharge port.

A stage 210 may be disposed at an inner lower surface of the plasma processing chamber 200 and may support the substrate W. The stage 210 may have a flat-plate form. In an embodiment, the stage 210 may include an electrostatic chuck for fixing the substrate W using an electrostatic force. The electrode 220 may be disposed at an inner upper portion of the plasma processing chamber 200 to face the stage 210. The electrode 220 may be parallel to the stage 210 and may be spaced apart therefrom by a distance. The RF power supply unit 230 may apply high-frequency energy into the plasma processing chamber 200 to form an electric field, and, thus, plasma may be generated in the plasma processing chamber 200.

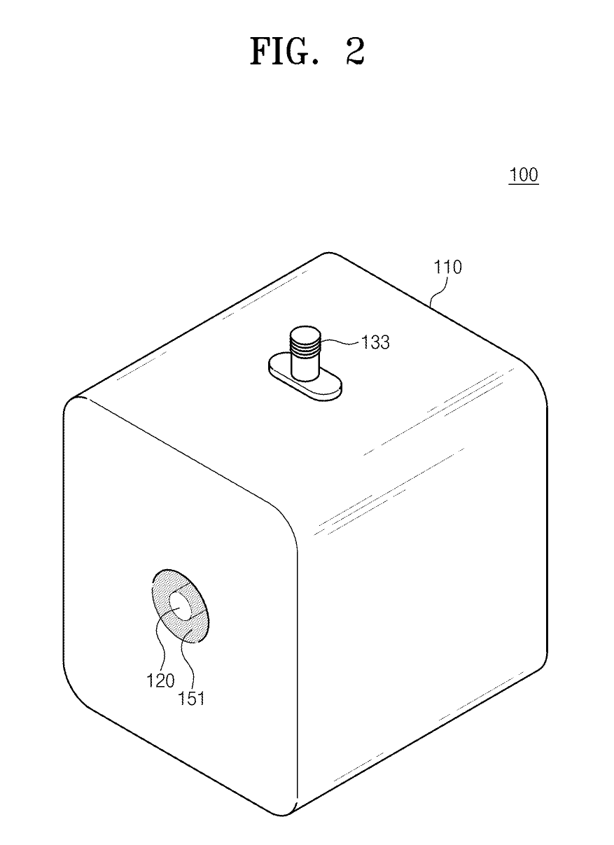

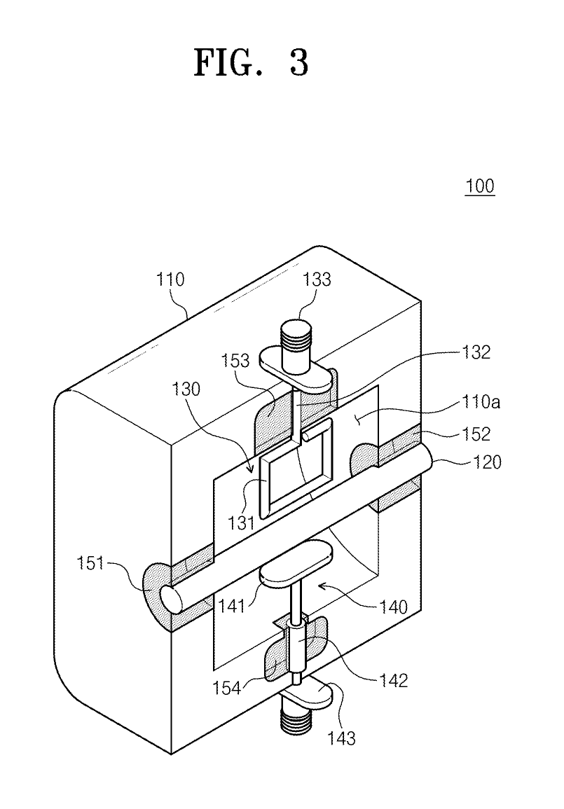

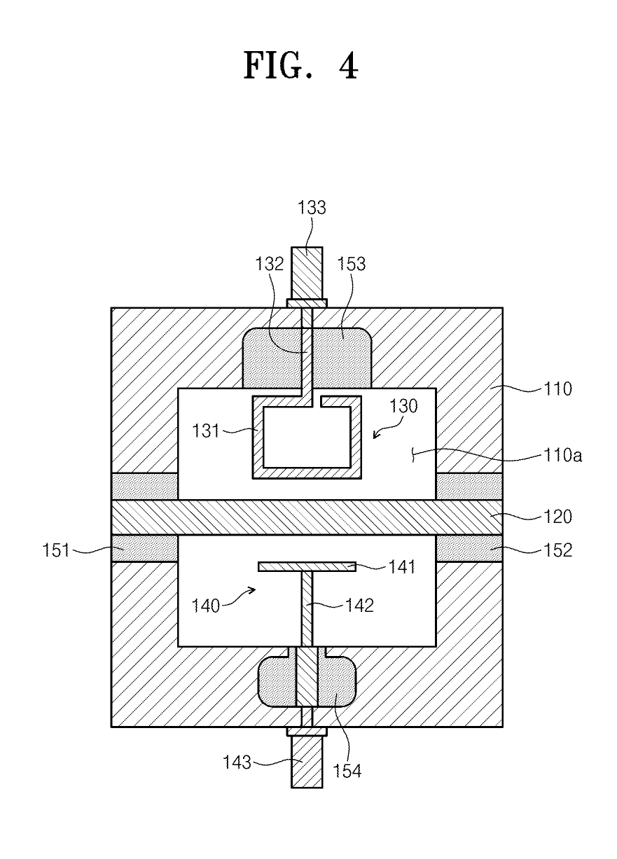

FIG. 2 is a perspective view of a current sensor 100 according to an embodiment of the inventive concept, FIG. 3 is a partially-cut perspective view of a current sensor 100 according to an embodiment of the inventive concept, and FIG. 4 is a vertical cross-sectional view of a current sensor 100 according to an embodiment of the inventive concept. The current sensor 100 according to embodiments of the inventive concept may be implemented with a voltage-current sensor (e.g., VI sensor) which is capable of measuring a current and a voltage of an RF power signal at the same time. Referring to FIG. 1 to FIG. 4, the current sensor 100 according to an embodiment of the inventive concept may include a housing 110, a signal transmission unit 120, a current measurement probe 130, a voltage measurement probe 140, and a signal processing unit 160.

The housing 110 may include a hollow portion 110a therein. The signal transmission unit 120, the current measurement probe 130, and the voltage measurement probe 140 may be installed in the hollow portion 110a of the housing 110. The housing 110 may be provided in the form of a cube or a cylinder or in any other form. The hollow portion 110a may be formed in a cylinder shape which is symmetrical with the signal transmission unit 120 as the axis.

The signal transmission unit 120 may be a conductor and may transmit an RF power signal. Opposite ends of the signal transmission unit 120 may be supported by the housing 110. The signal transmission unit 120 may be provided in a rod shape having a circular cross section. One end of the signal transmission unit 120 may be connected to the RF power supply unit 230, and the other end of the signal transmission unit 120 may be connected to the plasma processing chamber 200.

The current measurement probe 130 may be disposed at a side of the signal transmission unit 120 to be spaced apart from the signal transmission unit 120 and may have a loop structure to partition an area which links together with a magnetic field induced according to the RF power signal transferred through the signal transmission unit 120. The current measurement probe 130 may be formed of a conductor through which an induced current flows according to the magnetic flux changed by the RF power signal.

The current measurement probe 130 may include a loop member 131, a connecting portion 132, and a connector 133. The loop member 131 may be disposed in the hollow portion 110a to be spaced apart by a predetermined distance from the signal transmission unit 120. The loop member 131 may be coupled with the signal transmission unit 120 and may be spaced apart from the signal transmission unit 120 along a length direction of the signal transmission unit 120.

The loop member 131 may have an open-loop shape, at one side of which a gap is formed, so as not to interfere with the generation of an induced current according to an RF AC signal and so as to minimize power loss due to a DC current. The gap may be formed between an end portion of a conductor, forming the loop member 131, and the connecting portion 132. The loop member 131 may be installed to partition an area which substantially perpendicularly links together with a magnetic field generated by an RF power signal of the signal transmission unit 120 and to be disposed on the same plane as the signal transmission unit 120. The connecting portion 132 may be extended to pass through the housing 110 from one end of the loop member 131. The connector 133 may be disposed on an outer surface of the housing 110 to connect the connecting portion 132 and the signal processing unit 160.

According to embodiments of the inventive concept, as a magnetic flux is increased due to an increase in a magnetic field which passes through a large loop area of a rectangular shape formed by the loop member 131, a current sensor may more precisely detect a change in a current value of the RF power signal by measuring an induced current, thereby making it possible to accurately measure the current value of the RF power signal in the signal transmission unit 120.

The voltage measurement probe 140 may be disposed in the hollow portion 110a to be spaced apart by a predetermined distance from the signal transmission unit 120. The voltage measurement probe 140 may be disposed to be opposite to the current measurement probe 130 with the signal transmission unit 120 as the center. The voltage measurement probe 140 may be formed of a conductor so as to detect an intensity of an electric field formed by a power signal transferred through the signal transmission unit 120. The voltage measurement probe 140 may be disposed in the hollow portion 110a to be spaced apart by a predetermined distance from the signal transmission unit 120. The voltage measurement probe 140 may include a probe member 141 of a flat-plate shape, a connecting portion 142 extended from the probe member 141 to pass through the housing 110, and a connector 143 disposed on an outer surface of the housing 110 to connect the connecting portion 142 and the signal processing unit 160.

Insulating materials 151 to 154 may be respectively formed at a connecting portion (a jointing portion) between the housing 110 and the signal transmission unit 120, at a connecting portion between the housing 110 and the current measurement probe 130, and at a connecting portion between the housing 1110 and the voltage measurement probe 140. The insulating materials 151 to 154 may be formed of a dielectric material having low electrical conductivity such as Teflon. Micro-arcing may be prevented between the signal transmission unit 120 and the current measurement probe 130 or the voltage measurement probe 140 by the insulating materials 151 to 154.

The signal processing unit 160 may measure an inducted current which is induced at the current measurement probe 130 by the magnetic field generated according to the RF power signal transferred through the signal transmission unit 120 and may calculate a current value of the power signal transferred into the signal transmission unit 120 from a value of the inducted current thus measured. In addition, the signal processing unit 160 may measure a voltage formed at the voltage measurement probe 140 due to the electric field generated from the signal transmission unit 120 and may calculate a voltage value of the RF power signal transferred into the signal transmission unit 120 from a voltage value of the RF power signal transferred to the signal transmission unit 120. The signal processing unit 160 may measure a phase of the RF power signal from the measured current and voltage values of the RF power signal. Furthermore, the signal processing unit 160 may measure impedance of an RF load using the measured current, voltage, and phase values of the RF power signal.

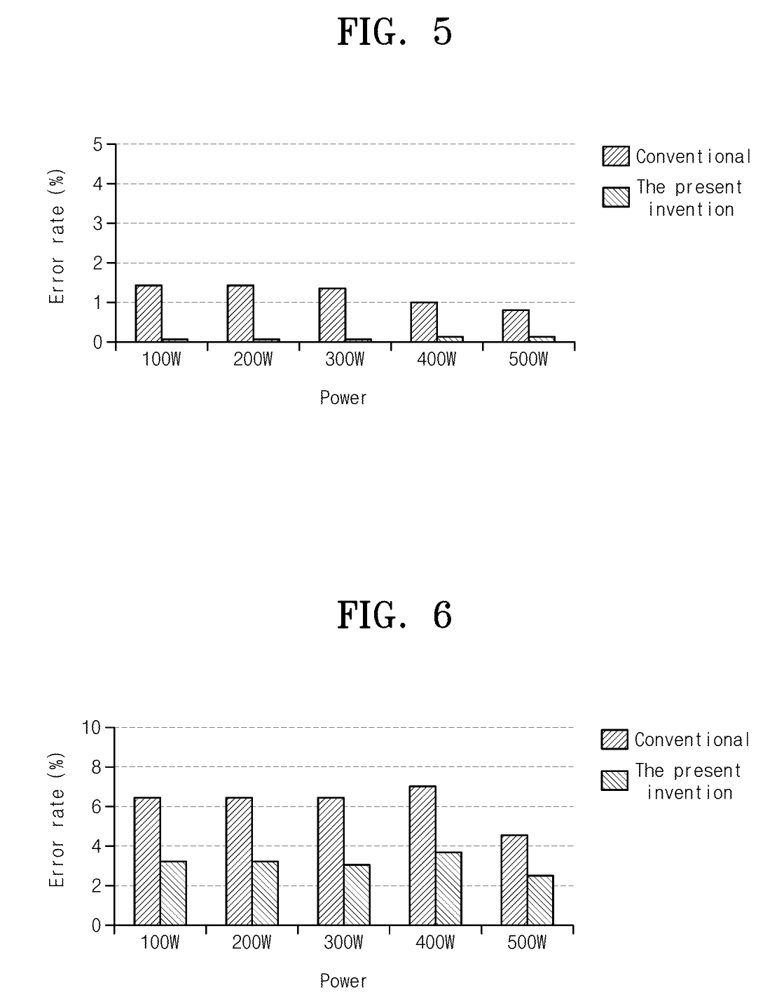

FIG. 5 and FIG. 6 are graphs illustrating a load measurement error of a current sensor 100, compared to a conventional example, according to an embodiment of the inventive concept. FIG. 5 is an experimental result for a 50-Ω dummy load, and FIG. 6 is an experimental result for a complex load. A bird diagnostic system (BDS) VI sensor of the bird electronics corporation was used as the conventional embodiment in FIGS. 5 and 6. As described the above, a measurement error rate of a current sensor according to embodiments of the inventive concept may be about 0.1% in the case of the 50-2 dummy load and may be about 3% in the case of plural loads, compared to the conventional embodiment in which a measurement error rate is about 1.2% in the case of the 50-2 dummy load and may be about 6% in the case of plural loads.

According to an embodiment of the inventive concept, it may be possible to provide a current sensor which is capable of measuring a current of an RF power source more accurately.

According to another embodiment of the inventive concept, it may be possible to provide a voltage-current sensor (e.g., a VI sensor) which is capable of measuring impedance of a load more accurately.

Embodiments described above are set forth in order to aid the understanding of the present inventive concept, not to limit the scope of the invention, various modifications possible embodiments from which also should be understood that within the scope of this inventive concept. Technical scope of the inventive concepts will be defined by the technical spirit of the appended claims, the technical scope of the inventive concepts is not limited to the wording of the claims ever substrate itself substantially value equivalent technical scope It should be understood that with respect to the effect to the inventive concepts.

While the inventive concept has been described with reference to exemplary embodiments, it will be apparent to those skilled in the art that various changes and modifications may be made without departing from the spirit and scope of the inventive concepts. Therefore, it should be understood that the above embodiments are not limiting, but illustrative.

What is claimed is:

1. A current sensor comprising:
a signal transmission unit through which a power signal is transmitted;
a current measurement probe spaced apart from a side of the signal transmission unit, the current measurement probe having a loop structure, the loop structure having an interlinkage area which interlinks with a magnetic field induced according to the power signal transmitted through the signal transmission unit; and
a signal processing unit measuring an induced current induced at the current measurement probe by the magnetic field, which is generated according to the power signal transmitted through the signal transmission unit, the signal processing unit calculating a current value of the power signal transmitted through the signal transmission unit using the measured induced current.

2. The current sensor of claim 1, further comprising:
a housing supporting opposite ends of the signal transmission unit, the housing having a hollow portion; and
a voltage measurement probe disposed in the hollow portion and formed in a flat-plate shape, the voltage measurement probe being spaced apart by a predetermined distance from the signal transmission unit, and including a conductor.

3. The current sensor of claim 2, further comprising:
insulating materials formed at a first connecting portion between the housing and the signal transmission unit, at a second connecting portion between the housing and the current measurement probe, and at a third connecting portion between the housing and the voltage measurement probe, respectively.

4. The current sensor of claim 2, wherein the signal processing unit is further configured to measure a voltage on the voltage measurement probe generated according to an electric field from the signal transmission unit and to calculate a voltage value of the power signal transmitted through the signal transmission unit using the measured voltage on the voltage measurement probe.

5. The current sensor of claim 4, wherein the signal processing unit further measures a phase of the power signal using the calculated current value and the calculated voltage value of the power signal transmitted through the signal transmission unit, to measure a load impedance.

6. The current sensor of claim 2, wherein the current measurement probe comprises:
a rectangular loop member disposed in the hollow portion and spaced apart by the predetermined distance from the signal transmission unit, the rectangular loop member including a conductor, and having an open-loop shape at one side of which a gap is formed;
a connecting portion extended to pass through the housing from one end of the rectangular loop member and including a conductor; and
a connector disposed at an external surface of the housing to connect the connecting portion and the signal processing unit.

7. A current sensor comprising:
a signal transmission unit through which a power signal is transmitted; and
a current measurement probe spaced apart from a side surface of the signal transmission unit and having a loop structure, the loop structure having an interlinkage area which interlinks with a magnetic field induced according to the power signal transmitted through the signal transmission unit.

8. The current sensor of claim 7, wherein the current measurement probe comprises:
a housing supporting opposite ends of the signal transmission unit, the housing including a hollow portion; and
a rectangular loop member spaced apart by a predetermined distance from the signal transmission unit, the rectangular loop member including a conductor, and having an open-loop shape at one side of which a gap is formed.

9. A plasma substrate processing apparatus comprising:
a plasma process chamber forming plasma to treat a substrate;
an RF power supply unit supplying an RF power to the plasma process chamber; and
a current sensor disposed between the RF power supply unit and the plasma process chamber and measuring a current value of the RF power,
wherein the current sensor comprises:
a signal transmission unit through which a power signal is transmitted;
a current measurement probe spaced apart from a side of the signal transmission unit and having a loop structure, the loop structure having an interlinkage area which interlinks with a magnetic field induced according to the power signal transmitted through the signal transmission unit; and
a signal processing unit measuring an induced current induced at the current measurement probe by a magnetic field, which is generated according to the power signal transmitted through the signal transmission unit, the signal processing unit calculating a current value of the power signal transmitted through the signal transmission unit using the measured induced current.

10. The current sensor of claim 9, wherein the current measurement probe comprises:
a housing supporting opposite ends of the signal transmission unit, the housing including a hollow portion; and
a rectangular loop member spaced apart by a predetermined distance from the signal transmission unit, the rectangular loop member including a conductor, and having an open-loop shape at one side of which a gap is formed.
